(19) United States
(12) Patent Application Publication
(10) Pub. No.: US 2024/0174478 A1
(43) Pub. Date: May 30, 2024

(54) Blanket Rolling Device

(71) Applicants: William Stolz, Kersey, CO (US); Tanner Stolz, Kersey, CO (US)

(72) Inventors: William Stolz, Kersey, CO (US); Tanner Stolz, Kersey, CO (US)

(21) Appl. No.: 18/350,835

(22) Filed: Jul. 12, 2023

Related U.S. Application Data
(60) Provisional application No. 63/428,422, filed on Nov. 29, 2022.

(51) Int. Cl. B65H 54/58

(52) U.S. Cl. CPC B65H 54/585

(57) ABSTRACT

A blanket rolling device is provided. The device is comprised of a male hitch, an axle, a vertical frame member, and a secondary axle. A construction blanket or other similar object may be placed between a first and second horizontal bar. By rotating the handle, the first and second horizontal bar rotate about the axis of the secondary axle, winding the construction blanket into a tight spiral. The axle acts as a guide to the construction blanket to smoothly roll the blanket up to the secondary axle.

### CROSS-REFERENCE TO RELATED APPLICATION

The present application claims priority to, and the benefit of, U.S. Provisional Application No. 63/428,422, which was filed on Nov. 29, 2022, and is incorporated herein by reference in its entirety.

### FIELD OF THE INVENTION

The present invention relates generally to the field of blankets. More specifically, the present invention relates to a blanket rolling device that allows a construction blanket or other similar object to be easily rolled for storage. Accordingly, the present disclosure makes specific reference thereto. Nonetheless, it is to be appreciated that aspects of the present invention are also equally applicable to other like applications, devices, and methods of manufacture.

### BACKGROUND

Construction projects, whether big or small, use many different types of equipment which can be dangerous to passersby, as well as the environment on which the construction is to take place. Oftentimes, preparing the site can be a time-consuming and laborious job, and can require multiple people to complete the task. These preparations, such as laying and rolling concrete blankets and construction fences, may also need to be set up and taken down each day, adding time and expense to the project. Further, this type of preparation equipment may take up a large amount of storage space, especially if not rolled tightly and properly secured.

Therefore, there exists a long-felt need in the art for a device that rolls blankets, construction fences, and other construction structures and items of the like for storage. More specifically, there exists a long-felt need in the art for a blanket rolling device that allows a single user to roll blankets and construction fences, such that the blanket or fence is tightly wound and secured, preventing it from unwinding during storage or transportation. Furthermore, there exists a long-felt need in the art for a blanket rolling device that can be secured to a vehicle such that it can be easily transported around a construction site.

The subject matter disclosed and claimed herein, in one embodiment thereof, comprises a blanket rolling device. The device is comprised of a male hitch, an axle, a vertical frame member, and a secondary axle, all preferably made of a metal to easily attach to a trailer hitch of a vehicle. During use, a construction blanket or other similar object may be placed between a first and second horizontal bar. By cranking a handle, the first and second horizontal bars rotate about the axis of the secondary axle, winding the construction blanket into a tight spiral. The axle acts as a guide to the construction blanket to smoothly roll the blanket up to the secondary axle.

In this manner, the blanket rolling device of the present invention accomplishes all the foregoing objectives and provides a device that can roll construction blankets and fences for storage. More specifically, the blanket rolling device can be operated by a single user to tightly wind and secure a construction blanket or fence, preventing it from unwinding during storage or transportation. Furthermore, the blanket rolling device can be secured to a vehicle such that it can be transported easily around a construction site.

### SUMMARY

The following presents a simplified summary to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises a blanket rolling device comprised of a male hitch, an axle, a vertical frame member, and a secondary axle. The device is designed to allow a construction blanket or fence to be tightly wound to be placed in storage or transported elsewhere. The device is preferably made of a metal material and can be secured to a trailer hitch of a vehicle via a male hitch of the device. An axle, further comprised of a roller, may extend from the male hitch. The roller allows a construction blanket or other similar object to be easily guided upwards on the device to the secondary axle, from which the construction blanket may be tightly wound. A height-adjustable, vertical frame member connects the axle to the secondary axle to accommodate differing sizes of construction blankets. A handle connected to one end of the secondary axle may be cranked to rotate the secondary axle. By cranking the handle, a vertical roller bar support that is attached to the other end of the secondary axle as well as a first horizontal bar and a second horizontal bar that extend from the vertical roller bar support rotate about the axis of the secondary axle. By placing a construction blanket in between the first horizontal bar and the second horizontal bar, the rotation of the two about the secondary axle may wind the construction blanket into a tight spiral.

The present invention is also comprised of a method of using the device. First, a device is provided comprised of a male hitch, an axle, a vertical frame member, and a secondary axle. Then, the male hitch of the device is secured to the trailer hitch of a vehicle. Next, one end of the construction blanket is placed between the first horizontal bar and the second horizontal bar. Then, the handle is cranked to rotate the secondary axle and roll the blanket compactly.

The present invention may also be comprised of a second method of using the device. First, a device is provided which is comprised of a male hitch, an axle, a vertical frame member, and a secondary axle. Then, the male hitch of the device is secured to the trailer hitch of a vehicle. Next, the vertical support member is set to the desired height and secured at said height via a pin. Then, one end of the construction blanket is placed between the first horizontal bar and the second horizontal bar. Then, the handle is cranked to rotate the secondary axle and roll the blanket compactly.

Accordingly, the blanket rolling device of the present invention is particularly advantageous as it can roll construction blankets and fences for storage and transportation. More specifically, the blanket rolling device can be secured to a vehicle such that it can be easily transported around a construction site. Furthermore, the blanket rolling device can be operated by a single user such that a construction blanket or other similar object may be tightly wound and secured to prevent it from taking up additional space in storage or unwinding during transportation. In this manner, the blanket rolling device provides a solution to rolling large industrial blankets.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a front view of one potential embodiment of a blanket rolling device of the present invention in accordance with the disclosed architecture;

FIG. 2 illustrates a perspective view of a potential embodiment of a blanket rolling device of the present invention while being used to roll a blanket in accordance with the disclosed architecture;

FIG. 3 illustrates a side view of a potential embodiment of a blanket rolling device of the present invention while being used to roll a blanket in accordance with the disclosed architecture;

FIG. 4 illustrates a flowchart of a method of using one potential embodiment of a blanket rolling device of the present invention in accordance with the disclosed architecture; and

FIG. 5 illustrates a flowchart of a method of using one potential embodiment of a blanket rolling device of the present invention in accordance with the disclosed architecture.

### DETAILED DESCRIPTION

The innovation is now described with reference to the drawings, wherein like reference numerals are used to refer to like elements throughout. In the following description, for purposes of explanation, numerous specific details are set forth to provide a thorough understanding thereof. It may be evident, however, that the innovation can be practiced without these specific details. In other instances, well-known structures and devices are shown in block diagram form to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments may be combined.

As noted above, there is a long-felt need in the art for a device that rolls blankets and construction fences for storage. More specifically, there exists a long-felt need in the art for a blanket rolling device that requires only a single user to roll blankets and construction fences such that the blanket or fence is tightly wound and secured, preventing it from unwinding during storage or transportation. Furthermore, there exists a long-felt need in the art for a blanket rolling device that can be secured to a vehicle such that it can be easily transported around a construction site.

The present invention, in one exemplary embodiment, is comprised of a blanket rolling device. The device is primarily comprised of a male hitch, an axle, a vertical frame member, and a secondary axle. The device is designed to secure a construction blanket or fence to the secondary axle such that when the secondary axle is rotated, the construction blanket or fence is tightly wound to be placed in storage or transported elsewhere.

More specifically, the device may be made of any material but is preferably made of a metal material. The device is comprised of a male hitch capable of attaching to a trailer hitch of a vehicle. The male hitch is further comprised of an opening and a fastener. The fastener is preferably a hitch pin that can be placed through the opening of the male hitch and an opening of the trailer hitch to secure the male hitch to the trailer hitch of the vehicle. An axle comprised of a roller extends from the male hitch. The axle remains stationary while the roller may rotate freely about the axle to help feed a blanket or other object to a secondary axle to be tightly wound.

A vertical frame member may be fixedly attached to the axle and extend upwards. The height of the vertical frame member may be adjustable by securing a locking pin to the vertical frame member once the desired height is reached. Fixedly attached to the other end of the vertical frame member is the secondary axle. The secondary axle may rotate by the cranking motion of the handle. The handle may have a grip area to provide a user with a comfortable and sturdy place to grip the handle. A vertical roller bar support may be fixedly attached to the secondary axle and a first horizontal bar, and a second horizontal bar may extend from the vertical roller bar support. By cranking the handle, the first horizontal bar and the second horizontal bar rotate, providing the construction blanket, or other similar object, a surface to be rolled tightly around.

The present invention is also comprised of a method of using the device. First, a device is provided comprised of a male hitch, an axle, a vertical frame member, and a secondary axle. Then, the male hitch of the device is secured to the trailer hitch of a vehicle. Then, one end of the construction blanket is placed between the first horizontal bar and the second horizontal bar. Next, the handle is cranked to rotate the secondary axle and roll the blanket compactly.

The present invention may also be comprised of a second method of using the device. First, a device is provided comprised of a male hitch, an axle, a vertical frame member, and a secondary axle. Then, the male hitch of the device is secured to the trailer hitch of a vehicle. Next, the vertical support member is set to the desired height and secured at said height via a pin. Then, one end of the construction blanket is placed between the first horizontal bar and the second horizontal bar. Then, the handle is cranked to rotate the secondary axle and roll the blanket compactly.

Accordingly, the blanket rolling device of the present invention is particularly advantageous as it can roll construction blankets and fences for storage and transportation. More specifically, the blanket rolling device can be operated by a singular person such that a construction blanket or other similar object may be tightly wound and secured to prevent it from taking up additional space in storage or unwinding during transportation. Furthermore, the blanket rolling device can be secured to a vehicle such that it can be easily transported around a construction site. In this manner, the blanket rolling device provides a solution to rolling large industrial blankets.

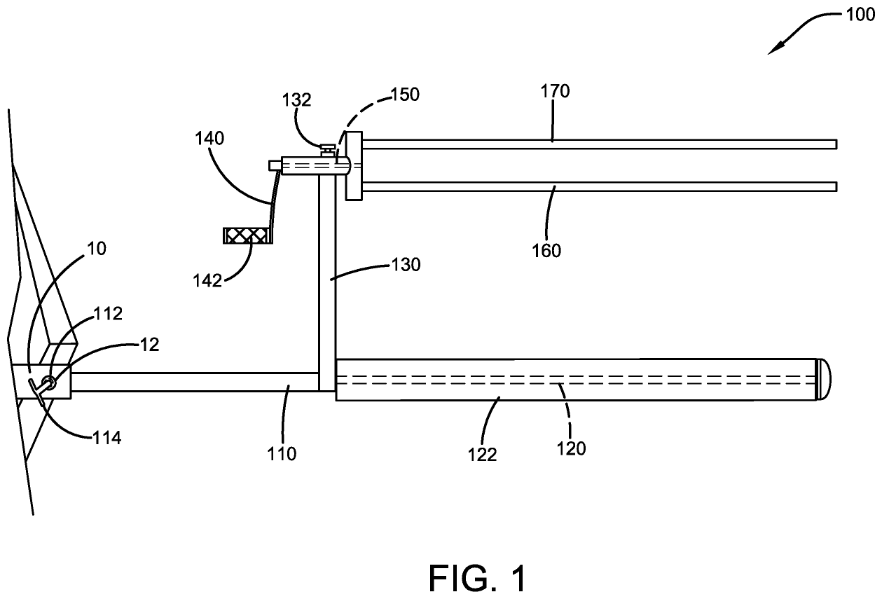

Referring initially to the drawings, FIG. 1 illustrates a front view of one potential embodiment of a blanket rolling device 100 of the present invention in accordance with the disclosed architecture. The device 100 is primarily comprised of at least one male hitch 110, at least one axle 120, at least one vertical frame member 130, and at least one secondary axle 150. The device 100 is designed to secure a construction blanket 20 or fence to the secondary axle 150 such that when the secondary axle 150 is rotated, the construction blanket 20 or fence is tightly wound to be placed in storage or transported elsewhere.

The device 100 may be made of any material such as a rubber or plastic material, but is preferably made of a metal material such as, but not limited to: aluminum, stainless steel, iron, copper, brass, nickel, carbon steel, gold, silver, etc. The device 100 may be attached to a trailer hitch 10 of a vehicle via a male hitch 110 of the device 100. The male hitch 110 is comprised of an at least one opening 112 and an at least one fastener 114. Preferably, the fastener 114 is a hitch pin that may be inserted through both the opening 112 of the male hitch 110 and an opening 12 of the trailer hitch 10 of a vehicle to secure the device 100 to a vehicle during use. However, the fastener 114 may be any fastener known in the art.

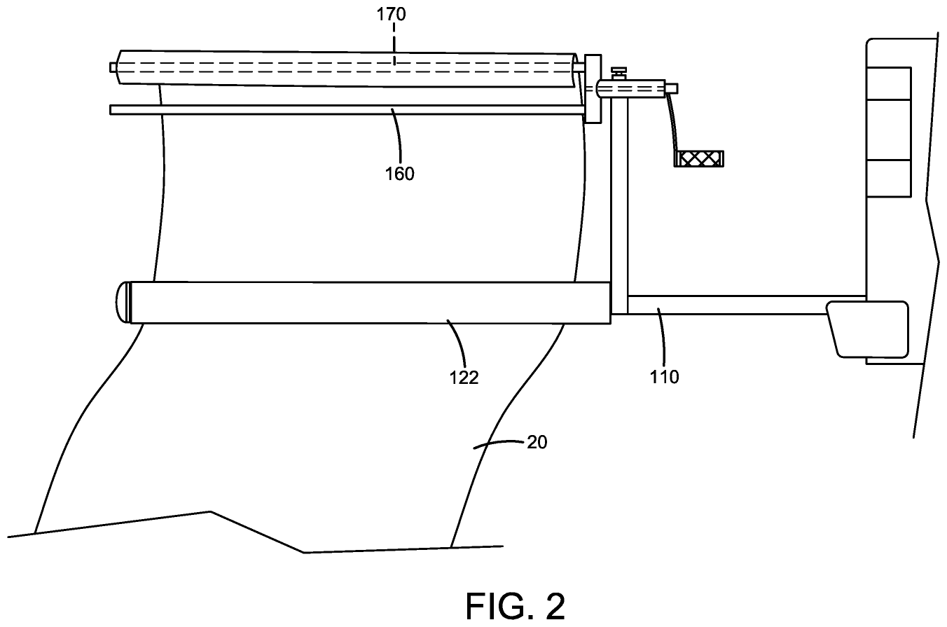

FIG. 2 illustrates a perspective view of a potential embodiment of a blanket rolling device 100 of the present invention while being used to roll a blanket 20 in accordance with the disclosed architecture. An axle 120 is attached to the male hitch 110 and is preferably comprised of an at least one roller 122 such that the axle 120 remains stationary and the roller 122 can freely rotate 360 degrees around the axle 120 horizontally. The roller 122 guides the construction blanket 20 (or another item of the like) upwards toward the secondary axle 150.

Further, a vertical frame member 130 connects the axle 120 to the secondary axle 150, which is preferably parallel to the first axle 120. The vertical frame member 130 is comprised of a locking pin 132 that may be used to adjust the height of the vertical frame member 130. By removing the locking pin 132 from the vertical frame member 130, the height of the vertical frame member 130 may be raised or lowered and then locked back into place by re-inserting the locking pin 132. The height of the vertical frame member 130 may be increased to accommodate varying sizes of construction blankets 20.

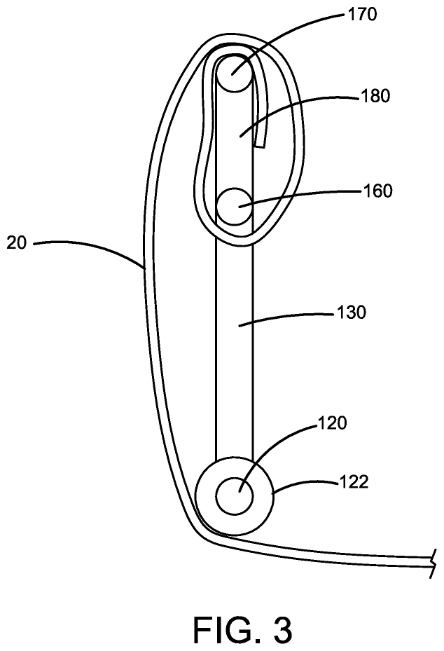

FIG. 3 illustrates a side view of a potential embodiment of a blanket rolling device 100 of the present invention while being used to roll a blanket 20 in accordance with the disclosed architecture. The secondary axle 150 is comprised of at least one handle 140 on one end and a vertical roller bar support 180 on the opposing end. The handle 140 may be rotated to rotate the secondary axle 150 360 degrees. A grip area 142 of the handle 140 may aid a user in grasping the handle 140 by including protrusions that conform to the human hand or by being made of a material, such as rubber, which provides additional grip.

As the handle 140 is cranked, the vertical roller bar support 180 rotates about the axis of the secondary axle 150 horizontally. A first horizontal bar 160, and a preferably parallel second horizontal bar 170 that extends from either end of the vertical roller bar support 180, also rotate about the axis of the secondary axle 150 providing the surfaces 160,170 for the construction blanket 20 to wrap around. In the preferred embodiment of the device 100, the secondary axle 150 is rotated by the rotating motion of a handle 140. However, in one potential embodiment, the secondary axle 150 may be rotated by a motor or other electronic device.

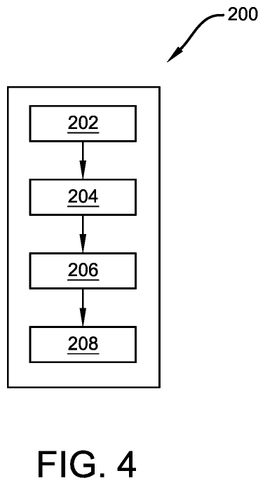

The present invention is also comprised of a method 200 of using the device 100, as seen in FIG. 4. First, a device 100 is provided comprised of at least one male hitch 110, at least one axle 120 comprised of at least one roller, at least one vertical frame member 130, and at least one secondary axle 150 [Step 202]. Then, the male hitch 110 of the device 100 is secured into the trailer hitch 10 of a vehicle via inserting at least one fastener 114 through the openings 12,112 of both structures [Step 204]. Then, the end of a construction blanket 20 (or another similar object or item to be wound into a roll) is placed behind the roller 122 around the first horizontal bar 160 and the second horizontal bar 170 [Step 206]. Next, the handle 140 is rotated to rotate the secondary axle 150 (and thereby the bars 160,170) to roll the blanket 20 compactly [Step 208].

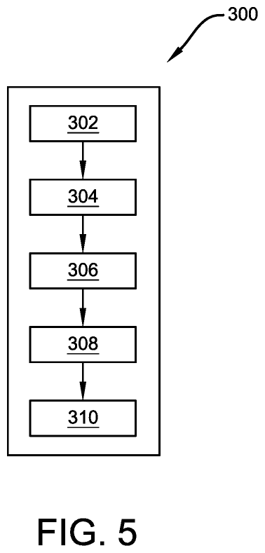

The present invention is also comprised of a second method 300 of using the device 100, as seen in FIG. 5. First, a device 100 is provided comprised of at least one male hitch 110, at least one axle 120 comprised of at least one roller, at least one vertical frame member 130, and at least one secondary axle 150 [Step 302]. Then, the male hitch 110 of the device 100 is secured into the trailer hitch 10 of a vehicle via inserting at least one fastener 114 through the openings 12,112 of both structures [Step 304]. Next, the vertical frame member 130 is raised or lowered to the desired height and then secured at said height via inserting at least one pin 132 through the frame member 130 [Step 306]. Then, an end of a construction blanket 20 (or another similar object or item to be wound into a roll) is placed behind the roller 122 around the first horizontal bar 160 and the second horizontal bar 170 [Step 308]. Next, the handle 140 is rotated to rotate the secondary axle 150 (and thereby the bars 160,170) to roll the blanket 20 compactly [Step 310]. The blanket rolling device 100 can be manually or mechanically operated, and is useful with a variety of flexible materials.

Certain terms are used throughout the following description and claims to refer to particular features or components. As one skilled in the art will appreciate, different persons may refer to the same feature or component by different names. This document does not intend to distinguish between components or features that differ in name but not structure or function. As used herein “blanket rolling device” and “device” are interchangeable and refer to the blanket rolling device 100 of the present invention.

Notwithstanding the foregoing, the blanket rolling device 100 of the present invention and its various components can be of any suitable size and configuration as is known in the art without affecting the overall concept of the invention, provided that they accomplish the above-stated objectives. One of ordinary skill in the art will appreciate that the size, configuration, and material of the blanket rolling device 100 as shown in the FIGS. are for illustrative purposes only, and that many other sizes and shapes of the blanket rolling device 100 are well within the scope of the present disclosure. Although the dimensions of the blanket rolling device 100 are important design parameters for user convenience, the blanket rolling device 100 may be of any size, shape, and/or configuration that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A blanket rolling device comprising:
a male hitch;
an axle comprised of a roller that rotates horizontally about the axle;
a vertical frame member attached to the axle;
a secondary axle attached to the vertical frame member; and
a handle that rotates the secondary axle.

2. The blanket rolling device of claim 1, wherein the roller can rotate 360 degrees around the axle horizontally.

3. The blanket rolling device of claim 1, wherein the secondary axle can rotate 360 degrees horizontally.

4. The blanket rolling device of claim 1, wherein the secondary axle is positioned above the axle.

5. The blanket rolling device of claim 1, wherein the axle is parallel to the secondary axle.

6. The blanket rolling device of claim 1, wherein the male hitch is comprised of an opening.

7. The blanket rolling device of claim 1 further comprised of a fastener.

8. The blanket rolling device of claim 7, wherein the fastener is comprised of a hitch pin.

9. A blanket rolling device comprising:
a male hitch comprised of an opening;
an axle comprised of a roller that rotates horizontally about the axle;
a height-adjustable vertical frame member attached to the axle;
a pin;
a secondary axle attached to the vertical frame member, the secondary axle comprised of a first horizontal bar and a second horizontal bar; and
a handle that rotates the secondary axle.

10. The blanket rolling device of claim 9, wherein the first horizontal bar is parallel with the second horizontal bar.

11. The blanket rolling device of claim 9, wherein the handle is comprised of a grip area.

12. The blanket rolling device of claim 11, wherein the grip area is comprised of a rubber material.

13. The blanket rolling device of claim 9, wherein the axle is parallel to the secondary axle.

14. The blanket rolling device of claim 9, wherein the height-adjustable vertical frame member receives the pin.

15. The blanket rolling device of claim 9 further comprised of a fastener.

16. The blanket rolling device of claim 15, wherein the fastener is comprised of a hitch pin.

17. A method of using a blanket rolling device, the method comprising the following steps:
providing a blanket rolling device comprised of a male hitch, an axle comprised of a roller, a vertical frame member, and a secondary axle;
securing the blanket rolling device to a trailer hitch of a vehicle by inserting the male hitch into the trailer hitch and placing a fastener through a first opening of the male hitch and a second opening of the trailer hitch;
placing an object behind the roller and around a first horizontal bar and a second horizontal bar of the secondary axle; and
rotating the secondary axle.

18. The method of claim 17, wherein the object is comprised of a blanket.

19. The method of claim 17, wherein the secondary axle is comprised of a handle.

20. The method of claim 17 further comprised of the steps of either raising or lowering the vertical frame member to a desired height and securing the vertical frame member at the desired height via a pin.
